(19) United States
(12) Patent Application Publication
(10) Pub. No.: US 2022/0045495 A1
(43) Pub. Date: Feb. 10, 2022

(54) JUNCTION BOX ASSEMBLY

(71) Applicant: ABB Schweiz AG, Baden (CH)

(72) Inventor: Phillip Taylor, Germantown, TN (US)

(21) Appl. No.: 16/986,753

(22) Filed: Aug. 6, 2020

(51) Int. Cl. H02G 3/14; E05D 7/10; E05D 7/02; H02G 3/08; H05K 5/02

(52) U.S. Cl. CPC H02G 3/14; E05D 7/1077; E05D 7/02; E05Y 2900/606; H05K 5/0226; H05K 5/0221; H02G 3/081

(57) ABSTRACT

A junction box assembly including a box and a selectively displaceable lid, the lid including one or more articulating lock sockets and one or more lock hinge sockets. Hinge arms can be pivotally coupled to the box, with a first hinge arm also being pivotally secured to an articulating hinge socket to accommodate pivotal displacement of the lid from the box, as well as pivotal displacement of the lid about a portion of the first hinge arm. A second hinge arm can be selectively removable from secure engagement with the lock hinge assembly. Further, a tamper resistant pin can extend through the upper head portion of the second hinge arm when the second hinge arm is engaged with the lock hinge socket so as to lock the second hinge arm to the lid, and thereby secure the lid at a closed position on the box.

### FIELD OF INVENTION

The present invention relates to junction boxes for electrical components, and more particularly, junction boxes having displaceable lids.

### BACKGROUND

Junction boxes, also referred to as enclosures, can be used to house a variety of types of electrical connections and components. At least certain types of junction boxes are manufactured to satisfy particular industry standards. For example, certain electrical boxes are manufactured to comply with specific standards and regulations of the National Electrical Manufacturers Association (NEMA). Included in these NEMA standards are requirements for Type 4X junction boxes that are constructed for either indoor or outdoor use, and which provide a degree of protection to personnel against access to hazardous parts. Under the NEMA Type 4X definition, such boxes further provide a degree of protection for the equipment inside the junction box against ingress of solid foreign objects, including falling dirt and windblown dust, as well as provide a degree of protection with respect to harmful effects on the equipment due to the ingress of water, including rain, sleet, snow, splashing water, and hose directed water, and a degree of protection against corrosive agents. Further, NEMA Type 4X junction boxes are also to be designed to be undamaged by the external formation of ice on the junction box.

Efforts to satisfy NEMA Type 4X requirements have included designing relatively heavy lids, which are intended to provide ample weight to secure a seal between the lid and a box. However, as such boxes can be positioned at elevated locations, including, for example, at locations at which access to the junction box involves a worker being elevated by use of a lift, maneuvering and storing such relatively heavy lids can be rather cumbersome, particularly while the worker is performing work within, and/or on electrical components for storage within, the junction box. Further, traditionally, such junction boxes have relied on the worker securing the lid in a closed position via engagement of mechanical fasteners with a hand tool, which is further complicated when the worker is operating at an elevated location.

Accordingly, although various junction boxes are available currently in the marketplace, further improvements are possible to provide a means for providing relatively low-cost and easy to use junction box.

### BRIEF SUMMARY

An aspect of an embodiment of the present application is a junction box assembly that can include a box having a perimeter wall that defines at least a portion of an interior area of the box, a first hinge bracket and a second hinge bracket each outwardly extending from an exterior side of the perimeter wall. The junction box assembly can further include a lid that is selectively displaceable about the box between a closed position and an open position, the lid being sized and positioned to cover at least a portion of an opening to the interior area when at the closed position and not extend over the opening when at the open position, the lid including an articulating hinge socket and a lock hinge socket, the lock hinge socket having a recess. The junction box assembly can also include a plurality of hinge arms, each hinge arm of the plurality of hinge arms including an upper head portion and a lower head portion at opposing ends of a body portion of the hinge arm. The lower head portion of a first hinge arm of the plurality of hinge arms can be pivotally coupled to the first hinge bracket, and the upper head portion of the first hinge arm can be selectively pivotally removable from the recess of the lock hinge socket. Additionally, the lower head portion of a second hinge arm of the plurality of hinge arms can be pivotally coupled to the second hinge bracket, and at least a portion of the upper head portion of the second hinge arm can be securely positioned within the articulating hinge socket, the lid being secured to, and pivotally displaceable about, the upper head portion of the second hinge arm as the lid is displaced between the open and closed positions.

Additionally, an aspect of an embodiment of the present application is a junction box assembly that includes a box having a box perimeter wall and a base wall that define at least a portion of an interior area of the box, a first pair of hinge brackets extending from an exterior side of a first sidewall of the box perimeter wall, a second pair of hinge brackets extending from an exterior side of a second sidewall of the box perimeter wall. The junction box assembly can also include a lid selectively that can be displaceable about the box between a closed position and an open position, the lid being sized and positioned to cover at least a portion of an opening to the interior area when at the closed position and not extend over the opening when at the open position, the lid further comprising. Additionally, the junction box assembly can further include a first articulating hinge socket and a second articulating hinge socket, the first and second articulating hinge sockets each including at least one arm having a first recess and which outwardly extends away from a lid perimeter wall of the lid. Further, the junction box assembly can include a first lock hinge socket and a second lock hinge socket, the first and second lock hinge sockets each including at least one arm having an upper surface having a second recess that inwardly extends into the at least one arm of the first and second lock hinge sockets. The junction box assembly can also include a first pair of hinge arms and second pair of hinge arms, the first and second pairs of hinge arms each including body portion, an upper head portion, and a lower head portion, the upper and lower head portions being on opposing sides of the body portion. With respect to the first pair of hinge arms, the upper head portion of a first hinge arm is positioned within the first recess of the at least one arm of the first articulating hinge socket and pivotally coupled to the lid, while the lower head portion of the first hinge arm is pivotally coupled to a first hinge bracket of the first pair of hinge brackets, and the upper head portion of a second hinge arm is positioned within the first recess of the at least one arm of the second articulating hinge socket and pivotally coupled to the lid, while the lower head portion of the second hinge arm is pivotally coupled to a second hinge bracket of the first pair of hinge brackets. With respect to the second pair of hinge arms (1) the upper head portion of a third hinge arm is selectively pivotally removable from the second recess of the at least one arm of the first lock hinge socket while the lower head portion of the third hinge arm is pivotally coupled to a third hinge bracket of the second pair of hinge brackets, and (2) the upper head portion of a fourth hinge arm is selectively pivotally removable from the second recess of the at least one arm of the second lock hinge socket while the lower head portion of the fourth hinge arm is pivotally coupled to a fourth hinge bracket of the second pair of hinge brackets.

These and other aspects of the present invention will be better understood in view of the drawings and following detailed description.

### BRIEF DESCRIPTION OF THE DRAWINGS

The description herein makes reference to the accompanying figures wherein like reference numerals refer to like parts throughout the several views.

FIG. 1 illustrates a front side perspective view of an exemplary junction box assembly according to an embodiment of the present application.

FIG. 2 illustrates a cross sectional view of the junction box assembly taken along line A-A in FIG. 1.

FIGS. 3 and 4 illustrate portions of the junction box assembly with the lid at different opened positions.

FIG. 5 illustrates a perspective view of a lock hinge socket according to an illustrated embodiment of the subject application.

FIG. 6 illustrates a perspective view of an articulation hinge socket according to an illustrated embodiment of the subject application.

FIG. 7 illustrates a perspective view of a lower hinge bracket according to an illustrated embodiment of the subject application.

FIG. 8 illustrates a perspective view of a hinge arm according to an illustrated embodiment of the subject application.

FIG. 9 illustrates a perspective view of a portion of an articulating hinge assembly according to an illustrated embodiment of the subject application.

FIG. 10A illustrates a perspective view of an articulating hinge assembly of a junction box assembly according to an embodiment of the present application.

FIG. 10B illustrates a cross sectional view taken along line B-B in FIG. 10A of a portion of the articulating hinge assembly.

FIG. 11 illustrates a front side perspective view of an exemplary tamper resistant locking pin of the junction box assembly.

FIG. 12 illustrates a perspective view of a locking hinge assembly according to an illustrated embodiment of the subject application.

FIGS. 13 and 14 illustrate perspective views of a locking hinge assembly at different open positions according to an illustrated embodiment of the subject application.

FIG. 15 illustrates a lock hook assembly for a junction box assembly according to an illustrated embodiment of the subject application.

The foregoing summary, as well as the following detailed description of certain embodiments of the present application, will be better understood when read in conjunction with the appended drawings. For the purpose of illustrating the application, there is shown in the drawings, certain embodiments. It should be understood, however, that the present application is not limited to the arrangements and instrumentalities shown in the attached drawings. Further, like numbers in the respective figures indicate like or comparable parts.

### DESCRIPTION OF THE ILLUSTRATED EMBODIMENTS

Certain terminology is used in the foregoing description for convenience and is not intended to be limiting. Words such as “upper,” “lower,” “top,” “bottom,” “first,” and “second” designate directions in the drawings to which reference is made. This terminology includes the words specifically noted above, derivatives thereof, and words of similar import. Additionally, the words “a” and “one” are defined as including one or more of the referenced item unless specifically noted. The phrase “at least one of” followed by a list of two or more items, such as “A, B or C,” means any individual one of A, B or C, as well as any combination thereof.

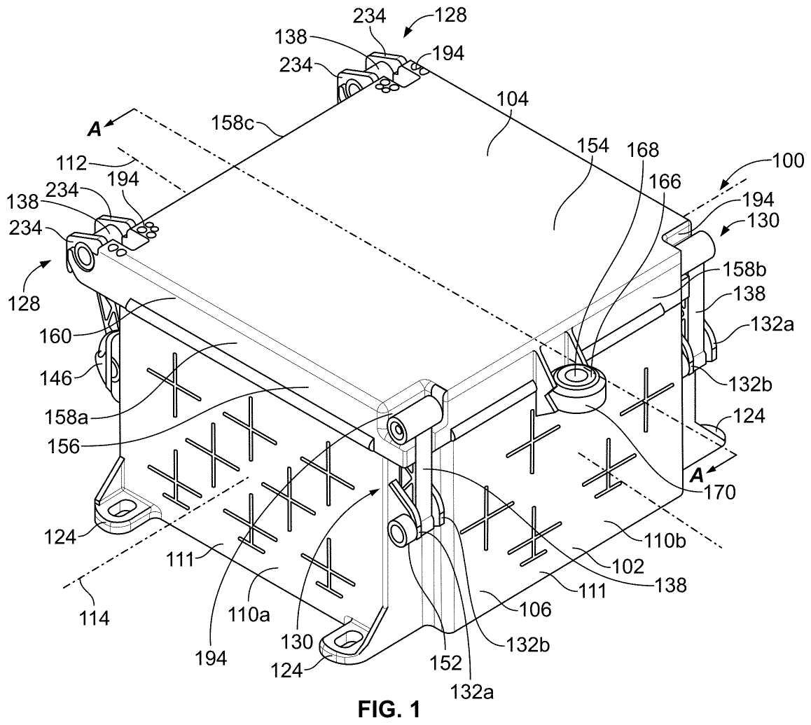

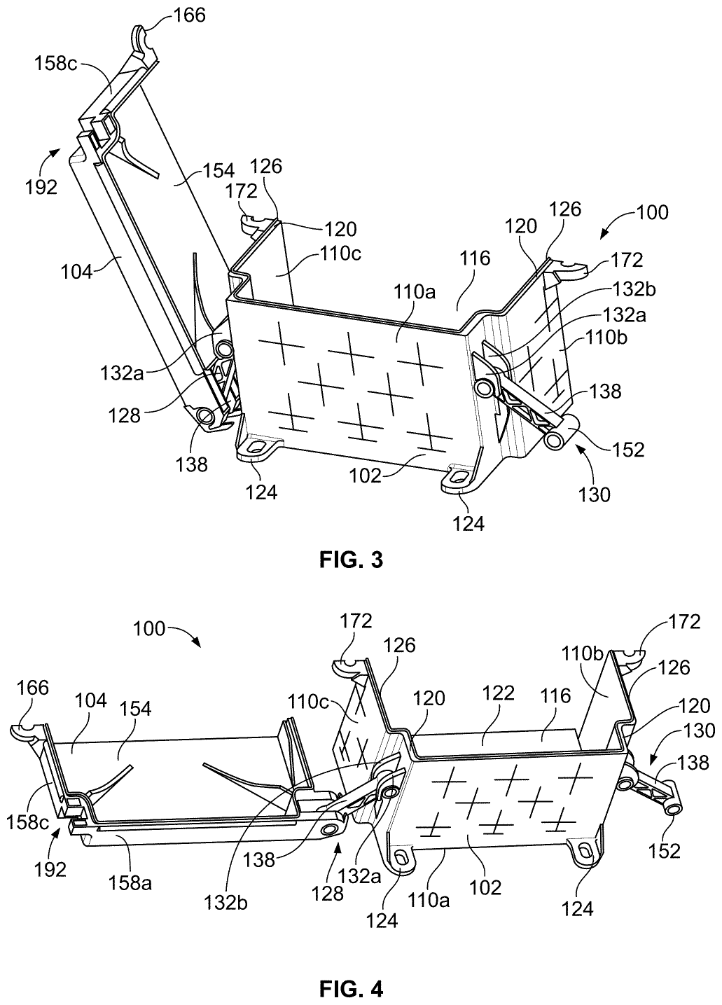

FIG. 1 illustrates a front side perspective view of a junction box assembly 100 according to an embodiment of the present application. The junction box assembly 100 can be configured for a variety of different types of applications and/or to satisfy particular industry standards and regulations. For example, according to certain embodiments, the junction box assembly 100 is configured to satisfy NEMA Type 4X standards. As shown, the junction box assembly 100 can include a box 102 and a lid 104, the lid 104 being selectively displaceable from the closed position, as shown FIG. 1, to an open position, such as, for example, a position shown in FIGS. 3 and 4.

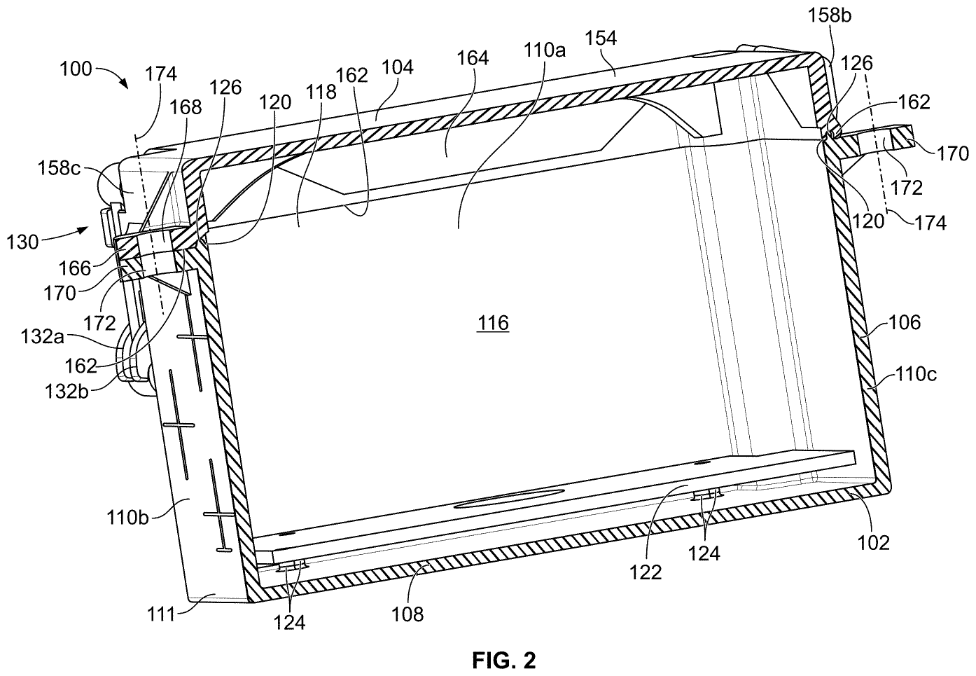

Referencing FIGS. 1 and 2, the box 102 comprises a box perimeter wall 106 and a base wall 108, the box perimeter wall 106 being positioned around, and adjoined to, the base wall 108. The box perimeter wall 106 can comprise a plurality of sidewalls 110a-c, including, for example, a front wall 110a and an opposing rear wall, as well as opposing sidewalls 110b, 110c. A lower edge 111 of each of the sidewalls 110a-c, and thus of the box perimeter wall 106, is adjoined to the base wall 108. According to certain embodiments, the front wall 110a and rear wall can have similar configurations, and the sidewalls 110b, 110c can have similar configurations such that the box can be symmetrical across a first centerline of symmetry 112 that is perpendicular to the sidewalls 110b, 110c, as well as symmetrical across a second centerline of symmetry 114 that is perpendicular to the front sidewall 110a and the rear sidewall. Thus, while FIG. 1 illustrates a front side perspective view of the box 102, according to certain embodiments, the rear side perspective view of the box 102 would have a similar or identical appearance.

While the box perimeter wall 106 and base wall 108 are depicted as having configurations that provide the box 102 with a generally rectangular or square box shape, the box perimeter wall 106 and base wall 108, as well as the number of sidewalls 110a-c, can be configured to provide the box 102 with a variety of other shapes, including, for example, circular and non-circular shapes. Additionally, as seen in FIG. 2, the box perimeter wall 106 and the base wall 108 can generally define an interior area 116 of the box 102 that is sized to house electrical components, cables, and wires within the box 102. The interior area 116 can generally extend from the base wall 108 to an opening 118 of the interior area 116 that is generally defined by upper edges 120 of the sidewalls 110a-c, and thus of the box perimeter wall 106.

While the box 102 and lid 104 can be constructed from a variety of different types of material, according to the illustrated embodiment, the box 102 and lid 104, as well as other portions of the junction box assembly 100, can be constructed from metallic or non-metallic materials, as well as a combination thereof. Further, the box 102 and/or lid 104 can be adapted to include, or be coupled to, one or more glands, seals, and/or conduits that can be used to accommodate the ingress/egress of cable(s) and/or wire(s) into/from the interior area 116 of the box 102.

As seen in FIG. 2, the interior area 116 can be configured to house a backer plate 122. The backer plate 122 and/or the opposing surface of the base wall 108 can include tabs 124 that can elevate or offset the backer plate 122 from the base wall 108. Such an offset configuration can accommodate the mounting of electrical devices to the backer plate 122 via use of mechanical fasteners, such as, for example, screws or bolts, without those mechanical fasteners passing into and/or through the base wall 108 in a manner that could compromise the integrity of the base wall 108 and/or compromise the ability of the junction box assembly 100 to satisfy certain industry standards (e.g., NEMA Type 4X standards). Further, the backer plate 122, as well as the box 102, can include a plurality of holes that align with mounting holes in the base wall 108 and/or which are configured for mounting of electrical devices to the backer plate 122. Additionally, the backer plate 122 can include one or more selectively removable knockout openings, such as, for example, partially stamped or formed areas that can be selectively removed to provide an opening through the backer plate 122 and/or box 102. Further, the backer plate 122 can have a cross sectional shape that is similar to the cross sectional shape of the interior area 116 formed by the box perimeter wall 106 such that the outer perimeter of the backer plate 122 can be position in relatively close proximity to, if not against, opposing inner surfaces of the adjacent portions of the box perimeter wall 106.

According to certain embodiments, the box 102 can further include a plurality of mounting brackets or feet 124 that are configured to secure the box 102, and thus the junction box assembly 100, to the an adjacent wall, for, and/or fixture, among other components and structures. According to the illustrated embodiment, two mounting brackets 124 outwardly extend in a direction away from the lower edge 111 of front sidewall 110a and the rear sidewall. Further, each mounting bracket 124 can include an aperture that is sized to receive insertion of a mechanical fastener, such as, for example, a screw or bolt, which can be used to mount the box 102, and thus the junction box assembly 100, at a vertical or horizontal orientation, among other orientations.

As seen in FIG. 2, a gasket 126 can be secured about the upper edge 120 of the sidewalls 110a-c, and thus along of the box perimeter wall 106. The gasket 126 can be configured to, when the lid 104 is secured to the box 102, provide a generally liquid tight or resistant seal between the lid 104 and the box 102. Moreover, the gasket 126 can be configured to assist the junction box assembly 100 with satisfying particular industry standards, including, for example, standards associated with the NEMA Type 4X junction boxes relating to the ingress of solid foreign objects and/or liquids into the interior area 116 of the box 107. According to certain embodiments, the gasket 126 can be a Form in Place (FIP) gasket.

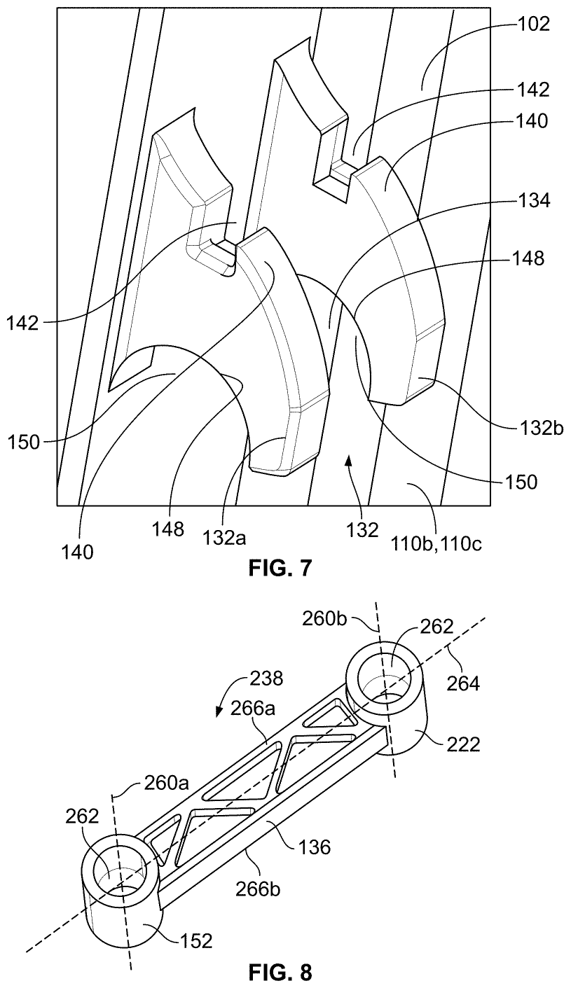

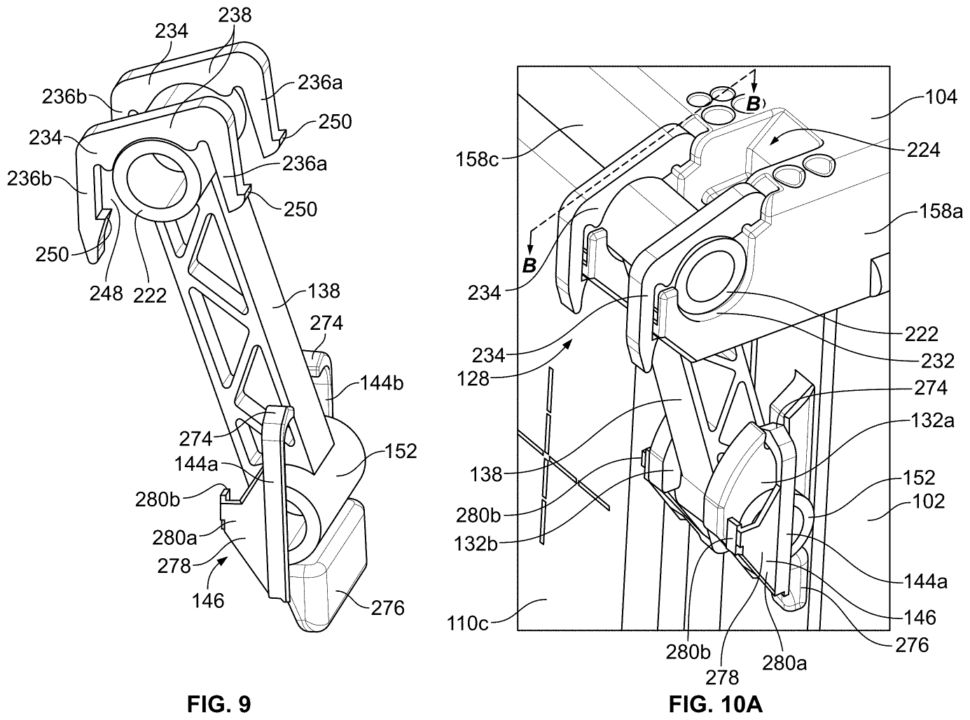

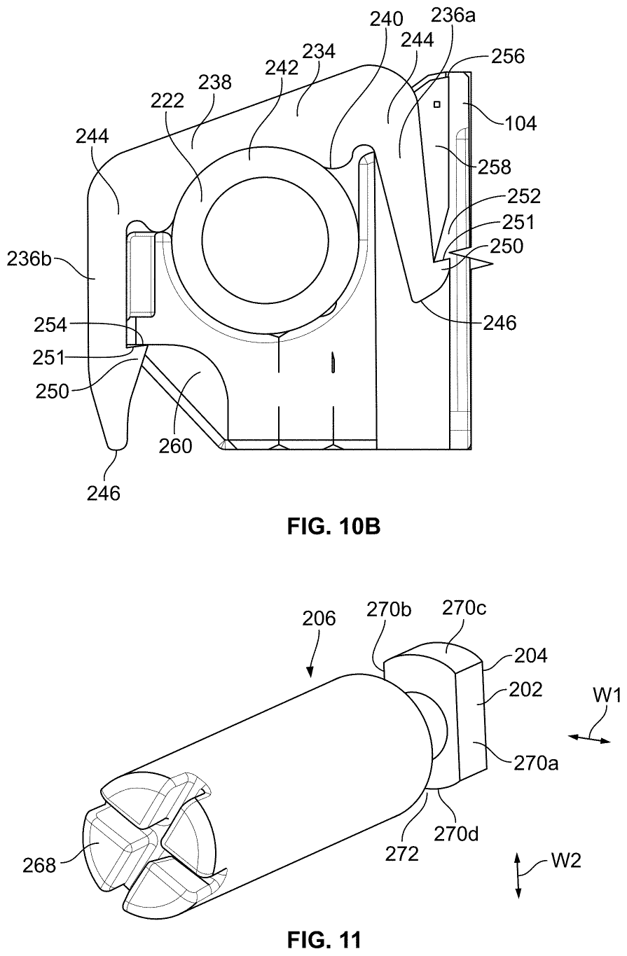

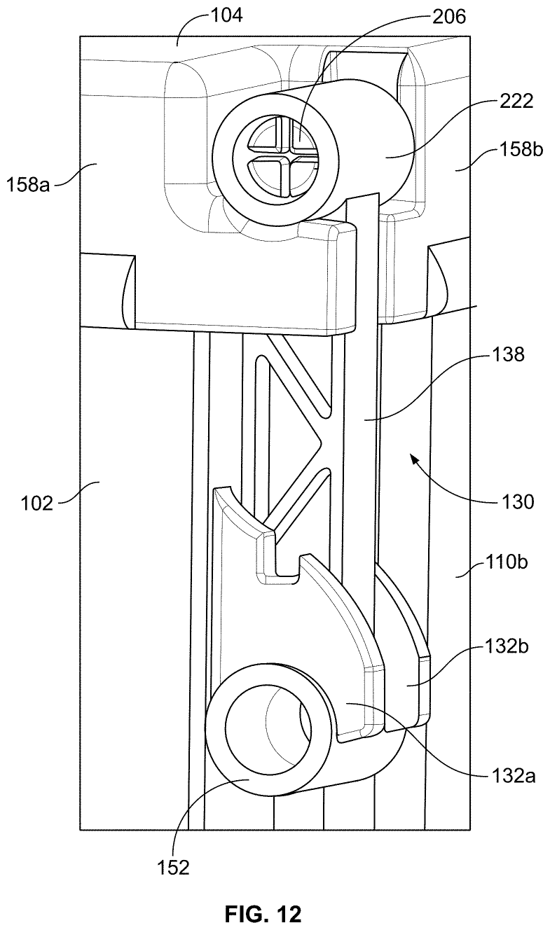

As seen in at least FIGS. 1 and 7, the box 102 can also include one or more lower hinge brackets 132 that can be positioned along an exterior side of the box perimeter wall 106. According to the illustrated embodiment, a lower hinge bracket 132 can be associated with each articulating hinge assembly 128 (FIG. 10A) and locking hinge assembly 130 (FIG. 12) of the junction box assembly 100, as discussed below. Additionally, according to the illustrated embodiment, the lower hinge bracket 132 can comprise a pair of bracket segments 132a, 132b that are separated from each other to define a space 134 therebetween that is sized to receive, as well as accommodate rotational displacement of, a lower portion of a body portion 136 of a hinge arm 138 (FIG. 8), as discussed below. An upper side 140 of each of the first and second bracket segments 132a, 132b can include a groove 142 that is sized to receive mating insertion of a leg 144a, 144b of a box hinge keeper 146 (FIGS. 9 and 10A), as discussed below, that can assist with retaining the hinge arm 138 in engagement with a corresponding first or second bracket segment 132a, 132b. The opposing lower side 148 of the first and second bracket segments 132a, 132b can include a pocket 150 that is configured to accommodate rotational or pivotable displacement of a lower head portion 152 of the hinge arm 138. Thus, as seen in FIGS. 7 and 8, the pocket 150 can be generally defined by a curved wall of the lower side 148 that extends into the associated first and second bracket segment 132a, 132b, and which has a size and shape that is similar, if not slightly larger, than a portion of the lower head portion 152 of the hinge arm 138 that will be positioned within the pocket 150. The curved configuration of the lower side 148 can have a length such that, when the lower head portion 152 of the hinge arm 138 is positioned in the pocket 150, the lower side 148 extends a distance around the lower head portion 152 of the hinge arm 138 that can prevent the lower head portion 152 of the hinge arm 138 from sliding out of the pocket 150 in a direction that is generally orthogonal to the sidewall 110b, 110c.

The lid 104 is configured to be positioned over the opening 118, and thus the interior area 116, of the box 102. The lid 104 can include an upper wall 154 and a lid perimeter wall 156. According to the illustrated embodiment, the lid perimeter wall 156 comprises a plurality of lid sidewalls 158a-c, including, for example, a front wall 158a and an opposing rear wall, as well as opposing sidewalls 158b, 158c. An upper edge 160 of each of the sidewalls 158a-c, and thus the lid perimeter wall 156, can be adjoined to the upper wall 154 of the lid 104. Further, an opposing lower surface 162 of the (FIG. 2) of the sidewalls 158a-c, and thus of the lid perimeter wall 156, and/or an inner portion of the lid perimeter wall 156, can be configured to engage the gasket 126 so as to at least partially compress the gasket 126 to form a seal when the lid 104 is secured to the box 102.

According to certain embodiments, the front wall 158a and rear wall of the lid perimeter wall 156 can have similar configurations such that the box 102 can be symmetrical generally across at least the first centerline of symmetry 112 that is perpendicular to the front sidewall 158a and rear sidewall of the lid perimeter wall 156. Further, the lid perimeter wall 156 can have a configuration, such as, for example, cross sectional shape, that is similar to that of the box perimeter wall 106 such that that the lid 104 covers the interior area 116. Additionally, as seen in FIG. 2, according to certain embodiments, the lid perimeter wall 156 and upper wall 154 can generally define a cavity 164 within the lid 104 that can, when the lid 104 is secured to the box 102, be in fluid communication with the opening 118 and interior area 116 of the box 102.

As seen in at least FIGS. 1 and 2, according to certain embodiments, the lid 104 can include at least one upper lock bracket 166 extending from the lid perimeter wall 156, the upper lock bracket 166 having an aperture 168. Similarly, the box 102 can have at least one corresponding lower lock bracket 170 that extends from the box perimeter wall 106 and which also includes an aperture 172. When the lid 104 is positioned over the interior area 116 and on the box 102, the apertures 168, 172 can be generally aligned with each other about a vertical centerline 174 that is generally perpendicular to the upper wall 154 of the lid 104 and base wall 108 of the box 102. Further, the apertures 168, 172 can be sized to receive a portion of a lock, such as, for example, a shackle or shank portion of a padlock, that can be used to securely maintain the lid 104 is a closed position on the box 102, as shown in FIG. 1. Accordingly, the portions of the upper and lower lock brackets 166, 170 around the associated aperture 168, 172 can have a size, such as, for example, width and thickness, that can prevent a lock that extends through the apertures 168, 172 from being pulled through the opposing walls of the upper and lower lock brackets 166, 170.

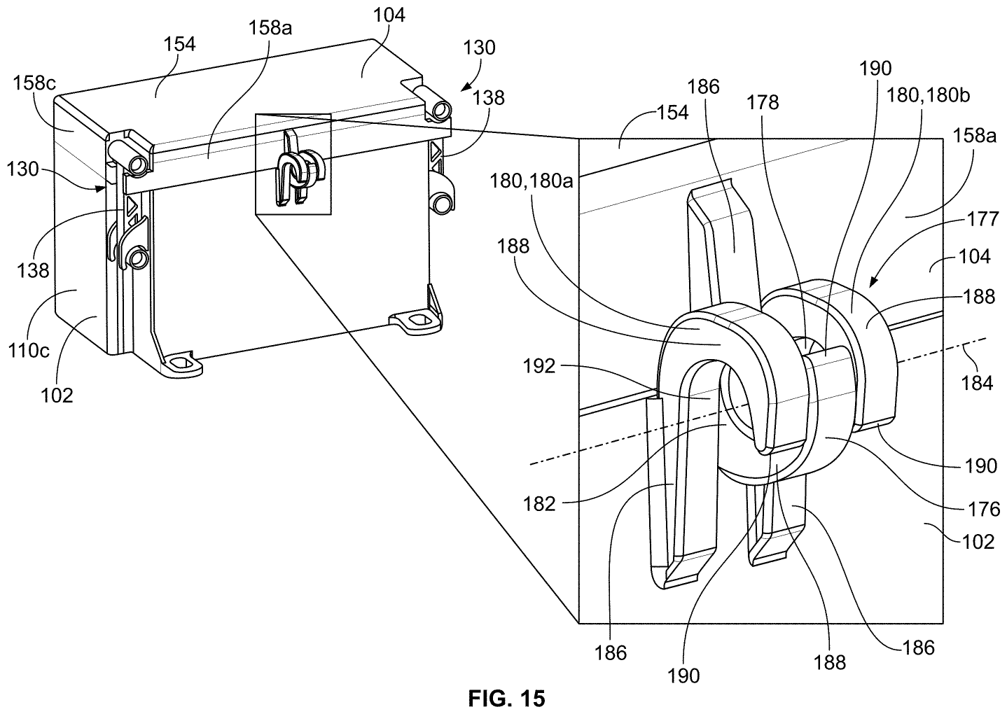

Additionally, or alternatively, as seen in FIG. 15, a lock bracket assembly 177 having one or more upper and lower lock brackets 176, 180 can be arranged such that, when the lid 104 is at the closed position relative to the box 102, an aperture 176 is provided through the upper and lower lock brackets 166, 170 that is positioned about a horizontal centerline 174 that is generally parallel to the upper wall 154 of the lid 104 and the base wall 108 of the box 102. Additionally, at least one of the upper and lower lock brackets 176, 180 can comprise a plurality of lock brackets that are separated from each other such that a lock bracket of the other of the upper and lower lock brackets 176, 180 can be positioned therebetween.

For example, according to the exemplary embodiment shown in FIG. 15, the lower lock bracket 180 comprises a first lower lock bracket 180a and a second lower lock bracket 180b, the first and second lower lock brackets 180a, 180b being separated from each other by a distance to provide a space therebetween that receives placement of at least a portion of at least one upper lock bracket 176 when the lid 104 is in the closed position. As shown, each of the first and second lower lock brackets 180a, 180b can include a first portion 186 that is attached to the adjacent sidewall 110a of the box 102, and a second portion 188 having a hook shape that can extend upwardly from the first portion 186, as well as outwardly from the box 102, before extending in a generally downwardly direction to a distal end 190 of the lock bracket 180a, 180b. Further, a distal end 190 of the second portion 188 can be detached from other portions of the lower lock bracket 180a, 180b. Thus, such a configuration can define an open ended aperture 192 that may extend along a portion of a lower surface of a mating locking device feature, such as, for example, a lower surface of a shackle of a padlock. Thus, as seen, the lower lock bracket 180a, 180b can extend across an upper surface of such a shackle, as well as the lower lock bracket 180a, 180b and/or box 102 being positioned adjacent to opposing sidewalls such a shackle. Thus, for example, as shown in FIG. 15, according to certain embodiments, the first and second lower lock brackets 180a, 180b can have generally upside down “J” shape.

The one or more upper lock brackets 176 can have a construction similar to the lower lock brackets 180a, 180b, with the exception that the first portion 186 is attached a sidewall 158a of the lid perimeter wall 156, and the second, or hook, portion 188 extends in a downward, as well as outwardly, direction before extending in a generally upwardly direction to a distal end 190 of the upper lock bracket 176. Thus, while the opening to the open ended apertures 182 of the first and second lower lock brackets 180a, 180b may be facing in a generally downwardly direction, the opening of the open-ended aperture 178 of the upper lock bracket 176 is instead facing in an opposing, generally upwardly direction. Accordingly, the orientation of the one or more upper lock brackets 176 may be opposite of the orientation of the first and second lower lock brackets 180a, 180b. Moreover, the upper bracket 176 can generally have a “J” shape in which the upper lock bracket 176 extends across a lower surface of the shackle of the padlock, as well as the upper lock bracket 176 and/or box 102 being positioned adjacent to opposing sidewalls of the shackle.

According to such an embodiment, when the lid 104 is in the closed positon, the aperture 178 of the upper lock bracket 178 is aligned with the apertures 182 of the first and second lower lock brackets 180a, 180b along a horizontal central axis 184 such that at least a portion of the locking device, such as, for example, the shackle of a padlock, can be positioned in at least a portion of the apertures 178, 182 of the upper and lower lock brackets 176, 180a, 180b. Thus, the upper and lower lock brackets 176, 180a, 180b can provide interferences that can prevent the lid 104 from being lifted to an open position, such as, for example, the open positions shown in FIGS. 3 and 4, as well as interferences that can prevent a locked locking device from being pulled, or otherwise removed, from the apertures 178, 182 of the upper and lower lock brackets 176, 180a, 180b.

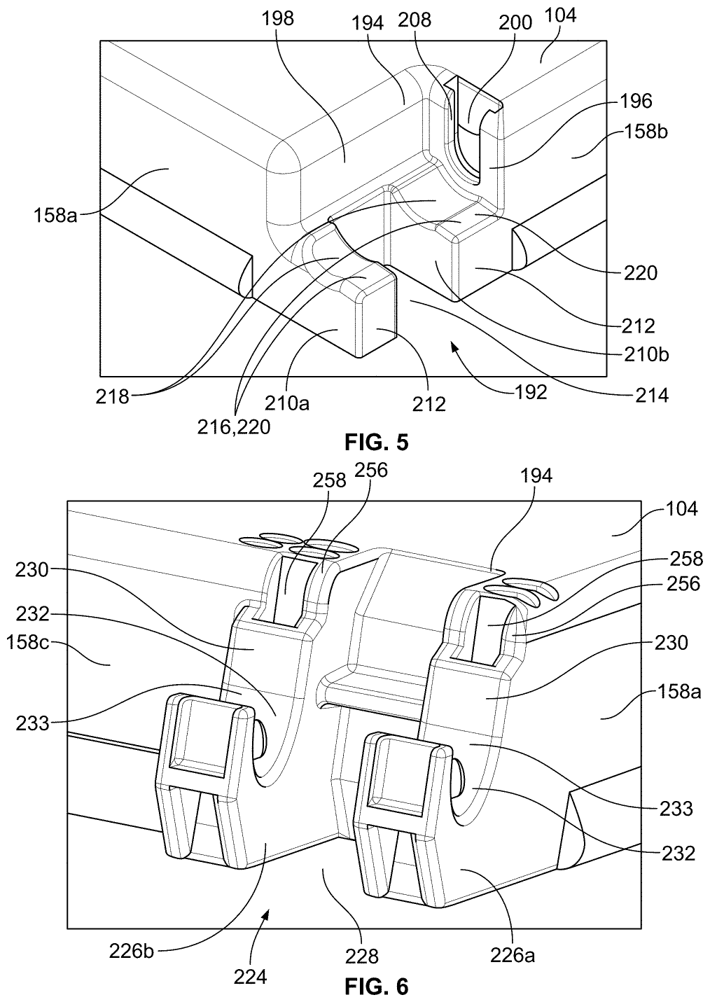

FIG. 5 illustrates a perspective view of a lock hinge socket 192 of the lid 104 according to an illustrated embodiment of the subject application. According to the illustrated embodiment, the lock hinge socket 192, which is part of the locking hinge assembly 130, can be positioned generally in a corner 194 of the lid 104, as shown in FIG. 1. Additionally, as shown by FIG. 1, according to certain embodiments, the lid 104 can include a plurality of lock hinge sockets 192, such as, for example, two lock hinge sockets 192. Further, each of the lock hinge sockets 192 can be generally positioned in different corners 194 of the lid 104. For example, as seen in FIG. 1, according to certain embodiments, the lock hinge socket 192 can be positioned in each corner 194 at opposing ends of the same lid sidewall 158b.

According to the illustrated embodiment, the lock hinge socket 192 can provide a recess in the associated corner 194 of the lid 104. According to such an embodiment, the lock hinge socket 192 includes a first recess wall 196 and a second recess wall 198, the first and second recessed walls 196, 198 downwardly extending from the upper wall 154 of the lid 104. Further, the first recess wall 196 can extend from, and be generally orthogonal to, the first sidewall 158b of the lid perimeter wall 156, and the second recess wall 198 can extend from, and be generally orthogonal to, the front sidewall 158a of the lid perimeter wall 156. Thus, the first recess wall 196 can be generally orthogonal to the second recess wall 198.

The first recess wall 196 can include an aperture or slot 200 that is configured to matingly engage a lock body 202 at a second end 204 of a tamper resistant locking pin 206 (FIG. 11), as discussed below. According to certain embodiments, one or more sides of the aperture 200 can include an overhang or extension 208 that can reduce a size of at least a portion of an opening of the aperture 200 along the first recess wall 196. The overhang(s) or extension(s) 208 can provide an interference that can accommodate ingress/egress of the lock body 202 of the tamper resistant locking pin 206 into/from the aperture 200 when the tamper resistant locking pin 206, and thus the lock body 202, is at a first orientation relative to the aperture 200, but prevent such ingress/egress of the lock body 202 of the tamper resistant locking pin 206 into/from the aperture 200 when the tamper resistant locking pin 206, and thus the lock body 202, is at a second, different orientation relative to the aperture 200.

The lock hinge socket 192 can also include first and second arms 210a, 210b that outwardly extend from the second recess wall 198 in the general direction of the first sidewall 158b of the lid perimeter wall 156. As seen in FIG. 5, a distal end 212 of the first and second arms 210a, 210b can be generally flush with, and may form part of, the first sidewall 158b. Additionally, a side portion of the first arm 210a may be flush with, and/or form part of, the front sidewall 158a of the lid perimeter wall 156, while an opposing edge of the second arm 210b can extend along the first recess wall 196. Additionally, the first and second arms 210a, 210b can generally define a gap 214 therebetween that is sized to receive, as well as accommodate rotational displacement of, an upper portion of a body portion 136 of the hinge arm 138 (FIG. 8) of the locking hinge assembly 130, as discussed below. According to the illustrated embodiment, the gap 214 between the first and second arms 210a, 210b can be positioned to be vertically aligned with the space 134 between the first and second bracket segment 132a, 132b. Thus, according to the illustrated embodiment, each lock hinge socket 192 can be associated with lower hinge bracket 132 that extends from the box 102, and which is positioned generally beneath at least a portion of the lock hinge socket 192 when the lid 104 is at a closed position on the box 102.

An upper surface 216 of both the first and second arms 210a, 210b can include a recess 218 that is offset from the distal end 212 of the first and second arms 210a, 210b, and thus inwardly offset from an adjacent sidewall 158b of the lid 104. Thus, a generally flat first portion 220 of the upper surface 216 can inwardly extend from the distal end 212 of the associated first and second arms 210a, 210b in the direction of the second recess wall 198 before reaching the recess 218 in the arm 210a, 210b. According to certain embodiments, the recesses 218 can have downwardly curved configurations that have sizes that are similar to a curvature of an adjacent portions of a upper head portion 222 of the hinge arm 138 (FIG. 8) that can be selectively positioned in, and against the surface of, the recesses 218. Further, the recesses 218 can have a depth relative to the first portion 220 of the upper surface 216 of the associated first or second arm 210a, 210b that can securely retain the upper head portion 222 of the hinge arm 138 in secure engagement with the recesses 218 during normal operating conditions. Moreover, such depth can provide a retention force that requires more than a minimal force to disengage the upper head portion 222 of the of the hinge arm 138 from the recesses 218, but which also can accommodate the worker being able to use the worker's hand and/or arm strength (without employing a separate tool) to pull the upper head portion 222 of the hinge arm 138 out of the recesses 218 and onto the adjacent flat first portions 220 of the upper surfaces 216 of the first and second arms 210a, 210b before sliding the upper head portion 222 to a position at which the upper head portion 222 disengages from the first and second arm 210a, 210b.

FIG. 6 illustrates a perspective view of an articulation hinge socket 224 of the lid 104 according to an illustrated embodiment of the subject application. The articulation hinge socket 224, which can be part of the articulating hinge assembly 128, can be positioned generally in a corner 194 of the lid 104, as well as extend outwardly beyond the corner 194, as shown in FIGS. 1 and 6. Additionally, as shown by FIG. 1, according to certain embodiments, the lid 104 can include a plurality of articulation hinge sockets 224, such as, for example, two articulation hinge sockets 224. Further, each of the articulation hinge sockets 224 can be generally positioned in different corners 194 of the lid 104, as well as in corners 194 different than the corners 194 that are occupied by the lock hinge sockets 192. Additionally, as seen in FIG. 1, according to certain embodiments, the articulation hinge sockets 224 can be positioned in each corner 194 at opposing ends of the same lid sidewall 158c. Thus, one side of the lid 104 can include a pair of articulation hinge sockets 224 at opposite corners 194 of the same sidewall 158c, while the opposing sidewall 158b can include, at opposite corners 194 of that sidewall 158b, a pair of lock hinge sockets 192.

The articulation hinge socket 224 can include first and second arms 226a, 226b that outwardly extend from the lid perimeter wall 156 in the general direction away from the second sidewall 158b of the lid perimeter wall 156. As seen in FIGS. 1 and 6, a first arm 226a can generally be a continuation of the front wall 158a of the lid 104, and the second arm 226b can extend in the same direction as the first arm 226a but generally from the adjacent sidewall 158c of the lid 104. Thus, a side portion of the first arm 226a can be flush with, and/or form part of, the front sidewall 158a of the lid perimeter wall 156. Additionally, the first and second arms 226a, 226b can generally define a gap 228 therebetween that is sized to receive, as well as accommodate rotational or pivotal displacement of, an upper portion of a body portion 136 of a hinge arm 138 (FIG. 8). According to the illustrated embodiment, the gap 228 between the first and second arms 226a, 226b can be positioned to be vertically aligned with a space 134 between a first and second bracket segments 132a, 132b of an associated lower hinge bracket 132. Thus, similar to the lock hinge sockets 192, according to the illustrated embodiment, each articulation hinge socket 224 can also be associated with a lower hinge bracket 132 that extends from the box 102, and which is positioned at a location to be generally beneath the at least a portion of the articulation hinge socket 224 when the lid 104 is at a closed position on the box 102.

An upper surface 230 of both the first and second arms 226a, 226b of the articulation hinge socket 224 can each include a downwardly curved wall 232 that defines a recess 233 that extends into the first and second arms 226a, 226b that has a shape and size that is similar to a curvature of an adjacent portion of a upper head portion 222 of the hinge arm 138 of the articulating hinge assembly 128 that can be selectively positioned in, and against the surface of, the wall 232. Further, the recess 233 can have a depth into the articulation hinge socket 224 that can at least assist in securely retaining the upper head portion 222 of the hinge arm 138 within the recesses 232 during normal operating conditions. Moreover, such depth can prevent the upper head portion 222 of the hinge arm 138 for at least being axially displaced out of the recess 233 in a generally horizontal direction.

The first and second arms 226a, 226b can each be configured for engagement with at least a portion of a lid hinge keeper 234 of the articulating hinge assembly 128 (FIGS. 9-10B). The lid hinge keeper 234 can be constructed from a variety of different metallic and non-metallic materials, including, for example, rubber and plastic. Further, the lid hinge bracket 234 can be configured to retain, as well as allow rotational displacement of, the upper head portion 222 of the hinge arm 138 within the corresponding recess 233 in the articulation hinge socket 224.

As seen in at least FIG. 9, according to the illustrated embodiment, the lid hinge keeper 234 can include first and second arms 236a, 236b that extend from opposing ends of a body portion 238 of the lid hinge keeper 234. Similar to the upper surface 230 of both the first and second arms 226a, 226b of the articulation hinge sockets 224, an inner surface 240 of the body portion 238 of the lid hinge keeper 234 can include a recess 242 having an upwardly curved recess 232 that has a shape and size that is similar to the curvature of an adjacent portion of the upper head portion 222 of the hinge arm 138 that can be selectively positioned in the recesses 232, and positioned against the inner surface 240 that generally defines the recesses 242. Further, the recess 242 can have a depth into the body portion 238 of the lid hinge keeper 234 that can at least assist in securely retaining the upper head portion 222 of the hinge arm 138 within the recesses 242 of the body portion 238 of the lid hinge keeper 234 during normal operating conditions. Such depth can prevent the upper head portion 222 of the hinge arm 138 from at least being axially displaced out of the recess 242 of body portion 238 in a generally horizontal direction.

The first and second arms 236a, 236b of the lid hinge keeper 234 can downwardly extend from a proximate end 244 of the arms 236a, 236b, which are attached to opposing ends of the body portion 238 of the lid hinge keeper 234, to a distal end 246 of the arms 236a, 236b. As seen, the first and second arms 236a, 236b and body portion 238 can be configured to provide the lid hinge keeper 234 with a generally a “C” shape configuration that can be oriented in a downward direction, as shown in FIG. 9. Thus, the first and second arms 236a, 236b can generally define a space 248 that can accommodate placement of a least a portion of the upper head portion 222 of the hinge arm 138 therebetween, as well as into the recesses 242 of the body portion 238 of the lid hinge keeper 234, as previously discussed. Additionally, the first and second arms 236a, 236b can also each include a retention tab or projection 250 that is configured to engage a mating projection 252 or surface 254 of the associated first and second arms 226a, 226b of the articulation hinge socket 224.

For example, as indicated by at least FIG. 10B, each of the first and second arms 226a, 226b of the articulation hinge socket 224 can each include, at a proximal end 256 of the first and second arms 226a, 226b, a cavity 258 that is sized to receive insertion of the first arm 236a of the lid hinge keeper 234. Within the cavity 258 is a mating projection 252 that is positioned for engagement with the retention tab 250 of the first arm 236a of the lid hinge keeper 234 in a manner that can assist in retaining the lid hinge keeper 234 in engagement with at least the associated first or second arm 226a, 226b of the articulation hinge socket 224. Moreover, as seen in FIG. 10B, an upper surface of 251 the retention tab 250 of the first arm 236a of the lid hinge keeper 234 can be positioned beneath the projection 252 in the cavity 258 such that the upper surface of the retention tab 250 abuts against a lower surface of the mating projection 252. Such engagement between the retention tab 250 of the first arm 236a of the lid hinge keeper 234 and the mating projection 252 in the cavity 258 of the associated first or second arm 226a, 226b can assist in preventing the lid hinge keeper 234 from being displaced at least in an upwardly vertical direction relative to at least the lid 104. Further, the first arm 236a can be constructed from a material, as well as configured to be partially inwardly deflected or deformed, by the projection 252 in the cavity 258 such that, at least when the retention tab 250 of the first arm 236a of the lid hinge keeper 234 is securely engaged with the projection 252 in the cavity 258, the first arm 236a of the lid hinge keeper 234 is asserting a generally biasing force against the projection 252 in the cavity 258. Further, according to certain embodiments, the first arm 236a, as well as the retention tab 250 of the first arm 236a, of the lid hinge keeper 234 can be configured to engage the projection 252 in the cavity 258 via a snap fit.

The retention tab 250 of the second arm 236b of the lid hinge keeper 234 can also be inwardly directed in generally the same direction as the retention tab 250 of the first arm 236a. The retention tab 250 of the second arm 236b can be configured to engage a projection or surface 254 generally located at a distal end of the associated first or second arm 226a, 226b of the articulation hinge socket 224. For example, as seen in FIGS. 10A and 10B, the distal end of the first and second arms 226a, 226b of the articulation hinge socket 224 each include a cavity 260 that provides a retention wall or surface 254 generally around the distal end of the first or second arm 226a, 226b of the articulation hinge socket 224. When the lid hinge keeper 234 is secured to the first or second arm 226a, 226b of the articulation hinge socket 224, an upper surface of the retention tab 250 of the second arm 236b can abut against the retention wall or surface 254 in a manner that can also assist in retaining the lid hinge keeper 234 in secure engagement with the corresponding first or second arm 226a, 226b of the articulation hinge socket 224. Moreover, such engagement between the retention tab 250 of the second arm 236b of the lid hinge keeper 234 and the retention wall or surface 254 can assist in preventing the lid hinge keeper 234 from being displaced at least in an upwardly vertical direction relative to at least the lid 104.

Additionally, similar to the first arm 236a of the lid hinge keeper 234, the second arm 236b can be constructed from a material, as well as configured to be partially inwardly deflected or deformed, by a portion of the distal end of the first or second arm 226a, 226b of the articulation hinge socket 224. Accordingly, at least when the retention tab 250 of the second arm 236b of the lid hinge keeper 234 is securely engaged with the retention wall or surface 254, the second arm 236b of the lid hinge keeper 234 can assert a biasing force against the distal end of the first or second arm 226a, 226b of the articulation hinge socket 224. Further, according to certain embodiments, the second arm 236b, as well as the retention tab 250 of the second arm 236b, of the lid hinge keeper 234 can be configured to engage the retention wall or surface 254 via a snap fit. Thus, as seen in FIGS. 1, 10A, and 10B, secure engagement of a lid hinge keeper 234 with each of the first and second arms 226a, 226b of the articulation hinge socket 224 can assist in securely retaining the upper head portion 222 of the hinge arm 138 within the articulation hinge socket 224, as well as accommodate rotational or pivotal displacement of the upper head portion 222 of the hinge arm 138 within the articulation hinge socket 224 and/or accommodate rotational or pivotal displacement of the lid 104 and lid hinge keeper 234 about the upper head portion 222 of the hinge arm 138.

As seen in FIG. 8, the upper and lower head portions 222, 152 of the hinge arm 138 can be adjoined to opposing ends of a body 136 of the hinge arm 138. Additionally, according to the illustrated embodiment, the upper and lower head portions 222, 152 can have generally cylindrical configurations that extend along central axes 260a, 260b in generally in the same direction. Further, at least the upper head portion 222, as well as the lower head portion 152, can have an aperture 262 that extends through the upper and lower head portions 222, 152 along the corresponding central axis 260a, 260b. The body 136 of the hinge arm 138 can extend between the upper and lower head portions 260a, 260b along a central axis 264 that extends in a direction that is generally orthogonal to the central axes 260a, 260b of the upper and lower head portions 222, 152. While the body 136 can have a variety of shapes and configurations, according to the illustrated embodiment, the body 136 is generally rectangular. Additionally, the hinge arm 138 can be constructed form a variety of types of metallic and non-metallic materials, including, for example, molded plastics, among other materials. Further, as seen in at least FIG. 8, the upper and lower head portions 222, 152 can extend beyond the opposing sides 266a, 266b of the body 136 such that the upper and lower head portions 222, 152 can be seated within the recesses 218, 232 or pocket 150 of the associated articulation or lock sockets 192, 224 and the one or more lower hinge brackets 132, respectively.

Referencing FIGS. 11 and 12, at least the locking hinge assembly 130 can also include a tamper resistant locking pin 206 that can be received within the aperture 262 of the upper head portion 222 of the hinge arm 138, and which can be selectively secured to the lid 104. The locking pin 206 can include opposing first and second ends 268, 204, the first end 268 being structure for engagement with a tool, such as, for example, a screwdriver, among other tools. As discussed above, the second end 204 of the locking pin 206 can include a lock body 202 that is configured to retain the locking pin 206 in engagement with the lid 104. Moreover, as discussed above, the lock body 202 can be configured, when the locking pin 206 is within the aperture 262 of the upper head portion 222 of the hinge arm 138, to be inserted into, as well as out of, the aperture 200 in the first recess wall 196 of the lock hinge socket 192 when the locking pin 206 is at a first angular orientation, but is configured to prevent insertion into, as well as prevent removed from, the same aperture 200 in the first recess wall 196 when the locking pin 206 is at a second angular orientation, the second angular orientation being different than the first angular orientation.

For example, according to the illustrated embodiment, the lock body 202 can have a first width (as indicated by the direction “w₁” in FIG. 11) between opposing sides 270a, 270b of the lock body 202 that is smaller than a width between the overhang or extension 208 of the aperture 200 in the first recess wall 196 of the lock hinge socket 192, and a second width (as indicated by the direction “w₂” in FIG. 11) between other opposing sides 270c, 270d of the lock body 202 that is larger than the width between the overhang or extension 208 of the aperture 200 in the first recess wall 196. Such differences in widths in the lock body 202 can be provided in a number of manners, including, for example, via removal of material along the opposing sides 270a, 270b of the cylindrical lock body 202 so that one set of opposing sides 270a, 270b of the lock body 202 are generally flat sides surfaces, while the other set of opposing sides 270c, 270d of the lock body 202 retain the larger, cylindrical shape, as seen in FIG. 11. Thus, when the locking pin 206 is at a first orientation in which the flat sides 270a, 270b of the lock body 206 are generally parallel to, or otherwise aligned with, the opposing overhangs or extensions 208 of the aperture 200 in the first recess wall 196, the lock body 202 can be axially displaced through the overhang or extension 208 and enter into the aperture 200. With the lock body 202 positioned in the aperture 200, the locking pin 206 can be rotated to a second orientation at which flat sides 270a, 270b are no longer parallel to, or are misaligned with, the opposing overhang or extension 208 of the aperture 200 in the first recess wall 196. Thus, at the second orientation, the larger width of the other set of opposing sides 270c, 270d of the lock body 202 may be positioned relative to the opposing overhangs or extensions 208 of the aperture 200 so as to prevent the lock body 202 from being pulled out of the aperture 200, thereby lockingly engaging the locking pin 206 with the lid 104. As a result, the locking pin 206 can lockingly engage the lid 104 in a manner that can prevent displacement of the upper head portion 222 of the hinge arm 138, in which the locking pin 206 is also positioned, from the lock hinge socket 192, thereby locking the position of the hinge arm 138 and lid 104 relative to the box 102.

Additionally, the locking pin 206 can include a recess 272 that is positioned between the lock body 202 and the first end 268 of the locking pin 206 that is sized to receive insertion of at least a portion of the opposing overhang or extensions 208 of the aperture 200 in the first recess wall 196 at least as the locking pin 206 is rotated between the first and second orientations. Further, when the locking pin 206 is to be unlocked, the locking pin 206 can be rotated from the second orientation to the first orientation so that the lock body can be axially displaced out of the aperture 200 in the first recess wall 196.

According to certain embodiments, at least a portion of the lock body 202 can be sized in a manner that can accommodate axial displacement of the locking pin 206 as the locking pin 206 enters, or is remove from, the aperture 200 in the first recess wall 196, while also retaining the locking pin 206 within the aperture 262 of the upper head portion 222 of the hinge arm 138. For example, a difference in sizes, such as, for example, diameters along one or more portions of the locking pin 206 and one or more portions of the aperture 262 of the of the upper head portion 222 of the hinge arm 138 can be utilized to prevent the locking pin 206 from being removed through one, or both, one ends of the aperture 262 of the upper head portion 222 of the hinge arm 138. Additionally, a biasing element, such as, for example, a spring, may be used to create a biasing force that seeks to displace the lock body 202 of the locking pin 206 out from the aperture 200 in the first recess wall 196. Thus, displacement of the lock body 202 into the aperture 200 in the first recess wall 196 may utilize a force that is sufficient to overcome the biasing force of the biasing element. According to such an embodiment, when the lock body 202 is secured within the aperture 200 in the first recess wall 196 and the locking pin 206, and thus lock body 202, is subsequently rotated from the second orientation to the first orientation, the biasing element can provide a sufficient force to displace the lock body 202 out from the aperture 200, and the locking pin 206 thus may no longer be securely engaged with the lid 104. With the loch body 202 removed from the aperture 200 in the first recessed wall 196, the hinge arm 138 in which the locking pin 206 is, or was, positioned, can be displaced from the locked position in the lock hinge socket 192 to an unlocked position in which the upper head portion 222 of the hinge arm 138 is outside of, and/or positioned away from, the lock hinge socket 192.

As also seen in at least FIGS. 9 and 10, each articulating hinge assembly 128 and locking hinge assembly 130 can include a box hinge keeper 146 having a pair of legs 144a, 144b, a portion of which is received within the groove 142 in the first and second bracket segments 132a, 132b, as discussed above. More specifically, as seen in FIGS. 9 and 10, a retention tab 274 can inwardly extend from a distal end of each of the legs 144a, 144b so as to be received in the groove 140 in the adjacent first or second bracket segment 132a, 132b. Additionally, the first and second legs 144a, 144b can be sized such that the legs 144a, 144b can define an area between the first and second legs 144a, 144b that can receive placement of both the first and second bracket segments 132a, 132b. Thus, each of the first and second legs 144a, 144b can extend from the distal end of each of the legs 144a, 144b along an outer surface of the adjacent first and second bracket segments 132a, 132b, to a proximate end of the legs 144a, 144b. The proximate ends of the first and second legs 144a, 144b can be adjoined to each other via an abutment body 276. The abutment body 276 can be positioned at a location at which the abutment body 276 can abut against a portion of the lower head portion 152 of the hinge arm 138. Moreover, the abutment body 276 and the curved lower side 148 of the pocket 150 of the bracket segments 132a, 132b can, when the box hinge keeper 146 is attached to the first and second bracket segments 132a, 132b, be on opposing sides of the lower head portion 152 of the hinge arm 138. Moreover, the abutment body 276 can be configured to be positioned at a location that prevents the lower head portion 152 of the hinge arm 138 from being removed from the pocket 150 of the bracket segments 132a, 132b, including from falling from a vertical positon out of the pocket 150, while also accommodating pivoting of the hinge arm 138 about the lower head portion 152.

The box hinge keeper 146 can also include extensions 278 having first and second walls 280a, 280b, the first wall 280a extending outwardly from the associated first or second leg 144a, 144b, and/or outwardly from the abutment body 276. The second wall 280b can be generally orthogonal to the first wall 280a, and can generally extend inwardly toward the outer surface of the adjacent first or second leg 144a, 144b. Thus, while the abutment body 276 can be positioned beneath the lower head portion 152 of the hinge arm 138, the extension 278 can be positioned adjacent to a portion of the end of the lower head portion 152 of the hinge arm 138, as well as along a portion of a sidewall of the lower head portion 152 that is generally orthogonal to the end of the lower head portion 152. Such a wrapping configuration of the extension 278 can further assist in retaining the lower head portion 152 in the pocket 150 of the associated bracket segments 132a, 132b.

Referencing FIG. 1, according to the illustrated embodiment, the junction box assembly 100 can also include a pair of articulating hinge assemblies 128 and a pair of locking hinge assemblies 130, each of the assemblies 128, 130 being shown in FIG. 1 in locked positions such that the lid 104 is retained on the box 102 in a closed position. In the event the lid 104 is to be opened, such as, for example, to a positon shown in FIG. 2 or 3, the locking pins 206, if any, in the apertures 262 of the upper head portions 222 of the hinge arms 138 of the locking hinge assemblies 130 can be rotated from the second orientation to the first orientation, as discussed above.

With the locking pin 206 in the first orientation, the lock body 202 can be removed from the aperture 200 in the first recess wall 196, thereby disengaging the locking pin 206 from a secure engagement with the lid 104. Upon the locking pins 206 being disengaged from the lid 104, the worker can then exert a force on the upper head portion 222 and/or body portion 136 of the hinge arm 138 of the hinge assembly 130 such that the upper head portion 222 is pivoted in a manner that pulls the upper head portion 222 out of the recesses 218 and onto and over the adjacent flat first portions 220 of the upper surfaces 216 of the first and second arms 210a, 210b of the lock hinge socket 192. Such displacement of the upper head portion 222 along the flat first portions 220 of the upper surfaces 216 can be accompanied by a degree of downward displacement of the lid 104, such as, for example, further compression of the gasket 126 resulting from the upper head portion 222 exerting a downward force against the upper surfaces 216 of the first and second arms 210a, 210b.

Moreover, the worker can exert a force against the hinge arm 138 that pivotally displaces the upper head portion 222 of the hinge arm 138 out of the associated lock hinge socket 192 and to an unlocked position, as shown for example, in FIGS. 3 and 4. Further, as the upper head portion 222 is being pivotally displaced out from the lock hinge socket 192, the associated lower head portion 152 is being rotatably displaced in the pocket 150 of the of the lower hinge bracket 132. Further, with the upper head portion 222 disengaged from the lock hinge socket 192, and thus at an open position (FIGS. 3 and 4), the box hinge keeper 146, and the associated engagement of the box hinge keeper 146 with the bracket segments 132a, 132b can retain the lower head portion 152 within the pocket 150 of the of the bracket segments 132a, 132b.

With the hinge arms 138 of the locking hinge assemblies 130 in the open position, the lid 104 can be pivotally opened about the articulating hinge assemblies 128. Such opening of the lid 104 can include the lower head portions 152 of the associated hinge arms 138 of the articulating hinge assemblies 128 being rotatably displaced in the pocket 150 of the lower hinge bracket 132 while also remaining secured within the pockets 150 via the associated box hinge keepers 146. However, unlike the hinge arms 138 of the locking hinge assembly 130, when the lid 104 is opened, the upper head portions 222 of the hinge arms 138 of the articulating hinge assemblies 128 remain within the associated articulation hinge sockets 224, such as, for example, via the engagement of the lid hinge keepers 234 with the associated articulation hinge socket 224. Thus, when the lid 104 is in the open position, the lid 104 remains secured to the junction box assembly 100 via the hinge arms 138 of the articulating hinge assemblies 128.

Additionally, according to such embodiments, the offsetting of the recess 232 in the outwardly extending first and second arms 226a, 226b of the articulating hinge assemblies 128, as discussed above, can provide a coped configuration that can accommodate a relatively wide degree of motion of the lid 104 relative to the box 102, as shown in FIGS. 3 and 4. For example, as seen in FIG. 4, according to certain embodiments, in addition to the hinges arms 138 being pivotally displaced via rotation of the lower head portions 152 of the hinge arms 138 within the pockets 150 of the bracket segments 132a, 132b, the lid 104 can also be pivotally displaced about the upper head portion 222 of those same hinge arms 138 of the articulating hinge assemblies 128. Such a configuration, including the configuration of the articulation hinge socket 224, can allow the upper wall 154 of the lid 104 to be lowered to a vertical height at which the upper wall 154 is generally coplanar with the base wall 108 of the lid 104 while the lid 104 still remains attached to the junction box assembly 100. Additionally, or optionally, as seen in FIG. 3, such a configuration can accommodate the lid 104 also being displaced to a location at which the lid 104 is nearly parallel to the adjacent sidewall 110c of the box 102 while the lid 104 still remains attached to the junction box assembly 100. Such configurations can enhance the worker's access to the interior area 116 of the box 102 without potential interference from the lid 104, while also allowing the worker to not have to retain a hold of the lid 104.

When the lid 104 is to be moved to the closed position (FIG. 1), the lower head portion 152 of the hinge arm 134 of the articulating hinge assemblies 128 can be rotatably displaced within the pocket 150 of the bracket segments 132a, 132b such that the hinge arm 138 can pivotally displace the lid 104 to a vertical height associated with the lid 104 being in the closed position. Additionally, the lid 104 can, via the articulation hinge socket 224, be rotated with the lid hinge keepers 234 about the upper head portion 222 such that the lid 104 is rotated to an orientation associated with the closed position, and moreover, is displaced to an orientation at which the lid 104 extends over the interior area 116 of the box 102. With the lid 104 extending over the interior area 116 of the box 102, the hinge arms 138 of the locking hinge assemblies 130 can be pivotally displaced from the open positions (FIGS. 3 and 4) to the locked position (FIG. 1). Such displacement of the hinge arms 138 of the locking hinge assemblies 130 can occur via rotation of the lower head portions 152 of the hinge arms 138 within the pockets 150 of the associated bracket segments 132a, 132b, and can continue until the upper head portions 222 of the hinge arms 138 are moved over the flat first portions 220 of the upper surfaces 216 of the first and second arms 210a, 210b and into the recesses 218 of the lock hinge socket 192. The locking pins 206 in the upper head portions 222 of the hinge arms 138 can then, at the first orientation, be reinserted into the aperture 200 in the first recess wall 196 and subsequently rotated to the second orientation so that the locking pins 206 are lockingly engaged with the lid 104.

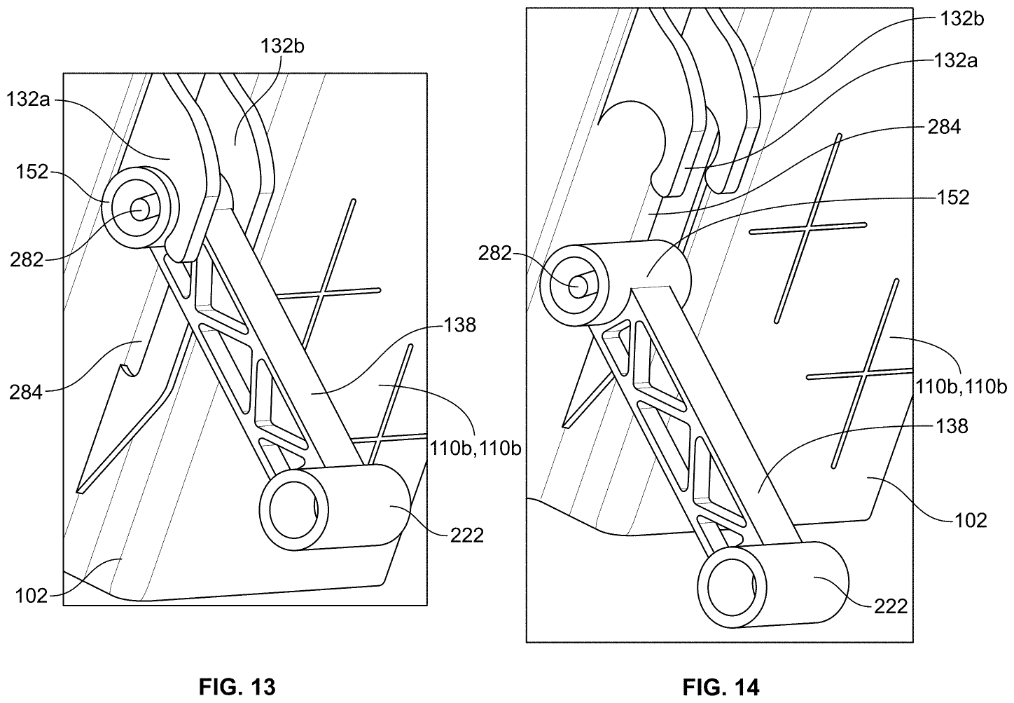

Referencing FIGS. 13 and 14, according to certain embodiments, rather than utilizing a box hinge keeper 146 to retain the hinge arms 138 in engagement with the box 102, the lower head portion 152 of the hinge arm 138 can be pivotally coupled to the bracket segments 132a, 132b and/or box 102, such as, for example, via a pin 282, among other connections. Further, according to certain embodiments, the lower head portion 152 of the hinge arm 138 can be coupled, via the pin 282, to a vertically elongated pin slot 284 that can accommodate slideable displacement of the pin 282. For example, as seen in FIG. 13, when the hinge arm 138 is to be rotated to a position associated with the lid 104 being at the closed position, the pin 282 can be positioned at a first, upper vertical height within the pin slot 284. Thus, with the pin 282 at the first, upper vertical height, the lower head portion 152 of the hinge arm 138 can also be at a corresponding first vertical height. However, when the lid 104 is at an open position, such as, for example, as shown in FIGS. 3 and 4, the pin 282 can be vertically displaced within the pin slot 284 to a second, lower vertical height, thereby lowering the vertical height of the lower head portion 152 of the hinge arm 138, and thus lowering a height of the hinge arm 138. Such a configuration can, when the lid 104 is at the open position, displace the hinge arms 138 further from the opening 118 to the interior area 116 of the box 102. Moreover, with respect to the articulating hinge assemblies 128, such a configuration can assist in lowering the lid 104 away from the opening 118 to the interior area 116 of the box 102. When the hinge arm 138 is to be subsequently returned to the locked position, such as, for example, in connection with securing the lid 104 to the box 102, the hinge arm 138 can be returned to the first vertical height by upwardly sliding the pin 282 within the pin slot 284. With the hinge arm 138 returned the first vertical height, the hinge arm 138 can be subsequently rotated into engagement with the lock hinge socket 192 so as to again secure the lid 104 to the box 102, as previously discussed.

While the invention has been described in connection with what is presently considered to be the most practical and preferred embodiment, it is to be understood that the invention is not to be limited to the disclosed embodiment(s), but on the contrary, is intended to cover various modifications and equivalent arrangements included within the spirit and scope of the appended claims, which scope is to be accorded the broadest interpretation so as to encompass all such modifications and equivalent structures as permitted under the law. Furthermore it should be understood that while the use of the word preferable, preferably, or preferred in the description above indicates that feature so described may be more desirable, it nonetheless may not be necessary and any embodiment lacking the same may be contemplated as within the scope of the invention, that scope being defined by the claims that follow. In reading the claims it is intended that when words such as “a,” “an,” “at least one” and “at least a portion” are used, there is no intention to limit the claim to only one item unless specifically stated to the contrary in the claim. Further, when the language “at least a portion” and/or “a portion” is used the item may include a portion and/or the entire item unless specifically stated to the contrary.

1. A junction box assembly comprising:
a box having a perimeter wall that defines at least a portion of an interior area of the box, a first hinge bracket and a second hinge bracket each outwardly extending from an exterior side of the perimeter wall;
a lid selectively displaceable about the box between a closed position and an open position, the lid being sized and positioned to cover at least a portion of an opening to the interior area when at the closed position and not extend over the opening when at the open position, the lid including an articulating hinge socket and a lock hinge socket, the lock hinge socket having a recess;
a plurality of hinge arms, each hinge arm of the plurality of hinge arms including an upper head portion and a lower head portion at opposing ends of a body portion of the hinge arm;
wherein the lower head portion of a first hinge arm of the plurality of hinge arms is pivotally coupled to the first hinge bracket, and the upper head portion of the first hinge arm is selectively pivotally removable from the recess of the lock hinge socket; and
wherein the lower head portion of a second hinge arm of the plurality of hinge arms is pivotally coupled to the second hinge bracket, and at least a portion of the upper head portion of the second hinge arm is securely positioned within the articulating hinge socket, the lid being secured to, and pivotally displaceable about, the upper head portion of the second hinge arm as the lid is displaced between the open and closed positions.

2. The junction box assembly of claim 1, further comprising a gasket formed into an upper edge of the perimeter wall of the box, at least a portion of the gasket forming a seal between the lid and the box when the lid is secured at the closed position.

3. The junction box assembly of claim 1, further including a locking pin at least partially positioned within the upper head portion of the first hinge arm, the lid having an aperture that is adjacent to a lock body of the locking pin when the upper head portion of the first hinge arm is positioned within the recess of the lock hinge socket, the lock body being sized and positioned for axial displacement into and from the aperture in the lid when the lock body is at a first angular orientation, and sized to prevent axial displacement of the lock body into and from the aperture when the lock body is at a second angular orientation, the second angular orientation being different than the first angular orientation, and
wherein the first hinge arm is not removable from the recess of the lock hinge socket when the lock body is positioned within the aperture of the lid.

4. The junction box assembly of claim 1, wherein the articulating hinge socket and the lock hinge socket are each positioned in a different corner of the lid.

5. The junction box assembly of claim 1, wherein the first and second hinge brackets extend from opposing sidewalls of perimeter wall of the box, each of the first and second hinge brackets having a first bracket segment and a second bracket segment, the first and second bracket segments being separated from each other by a space, a portion of the body portion of the first hinge arm being positioned in the space between the first and second bracket segments of the first hinge bracket when the lid is at the closed position, and a portion of the body portion of the of the second hinge arm being positioned in the space between the first and second bracket segments of the second hinge bracket when the lid is at the closed position.

6. The junction box assembly of claim 5, further including a box hinge keeper coupled to at least one of the first and second hinge brackets, the box hinge keeper including a first leg and a second leg, the first leg being attached to the first bracket segment and the second leg attached to the second bracket segment, the first and second legs each being attached to opposing ends of an abutment body of the box hinge keeper, the abutment body and the first and second bracket segments extending at least about a portion of opposing sides of the lower head portion of the adjacent first or second hinge arm.

7. The junction box assembly of claim 1, wherein the articulating hinge socket includes a curved recess that receives pivotal placement of the upper head portion of the second hinge arm, and wherein the junction box assembly further includes at least one lid hinge keeper, the at least one lid hinge keeper and the curved recess extending around opposing sides of the upper head portion of the second hinge arm, the at least one lid hinge keeper including at least one retention tab, an upper surface of the at least one retention tab positioned and configured to provide an abutting force against a surface of the articulating hinge socket that at least assists in securing the at least one lid hinge keeper to the articulating hinge socket.

8. The junction box assembly of claim 1, wherein at least one of the first hinge bracket and the second hinge bracket includes a pin slot sized to receive insertion of a pin that is coupled to the lower head portion of the corresponding first or second hinge arm, the pin slot configured to accommodate slideable displacement of the pin to adjust the associated first or second hinge arm between a first height and a second height, the second height being different than the first height.

9. The junction box assembly of claim 1, further including a lock bracket assembly comprising a plurality of lock brackets, at least two lock brackets of the plurality of lock brackets attached to one of the box and the lid, and at least one lock bracket of the plurality of lock brackets attached to the other of the box and the lid, the at least one lock bracket being positioned between the at least two lock brackets when the lid is at the closed positon,
wherein each lock bracket of the plurality of lock brackets comprises a hook portion that defines an aperture of the lock bracket, a distal end of the hook portion being separated from an adjacent portion of the associated lock bracket to define an opening to the aperture of the lock bracket, the opening of the at least one lock bracket being vertically offset from the opening of the at least two lock brackets when the lid is in the closed position, and
wherein, when the lid is at the closed position, each of the apertures of the plurality of lock brackets are aligned along a horizontal central axis.

10. A junction box assembly comprising:
a box having a box perimeter wall and a base wall that define at least a portion of an interior area of the box, a first pair of hinge brackets extending from an exterior side of a first sidewall of the box perimeter wall, a second pair of hinge brackets extending from an exterior side of a second sidewall of the box perimeter wall;
a lid selectively displaceable about the box between a closed position and an open position, the lid being sized and positioned to cover at least a portion of an opening to the interior area when at the closed position and not extend over the opening when at the open position, the lid further comprising:
a first articulating hinge socket and a second articulating hinge socket, the first and second articulating hinge sockets each including at least one arm having a first recess and which outwardly extends away from a lid perimeter wall of the lid; and
a first lock hinge socket and a second lock hinge socket, the first and second lock hinge sockets each including at least one arm having an upper surface having a second recess that inwardly extends into the at least one arm of the first and second lock hinge sockets;
a first pair of hinge arms and second pair of hinge arms, the first and second pairs of hinge arms each including body portion, an upper head portion, and a lower head portion, the upper and lower head portions being on opposing sides of the body portion,
wherein, for the first pair of hinge arms (1) the upper head portion of a first hinge arm is positioned within the first recess of the at least one arm of the first articulating hinge socket and pivotally coupled to the lid, while the lower head portion of the first hinge arm is pivotally coupled to a first hinge bracket of the first pair of hinge brackets, and (2) the upper head portion of a second hinge arm is positioned within the first recess of the at least one arm of the second articulating hinge socket and pivotally coupled to the lid, while the lower head portion of the second hinge arm is pivotally coupled to a second hinge bracket of the first pair of hinge brackets, and
wherein, for the second pair of hinge arms (1) the upper head portion of a third hinge arm is selectively pivotally removable from the second recess of the at least one arm of the first lock hinge socket while the lower head portion of the third hinge arm is pivotally coupled to a third hinge bracket of the second pair of hinge brackets, and (2) the upper head portion of a fourth hinge arm is selectively pivotally removable from the second recess of the at least one arm of the second lock hinge socket while the lower head portion of the fourth hinge arm is pivotally coupled to a fourth hinge bracket of the second pair of hinge brackets.

11. The junction box assembly of claim 10, wherein the at least one arm of the first articulating hinge socket extends outwardly from around a first corner of the lid, and the at least one arm of the second articulating hinge socket extends outwardly from around a second corner of the lid, the first and second corners being on the same side of the lid.

12. The junction box assembly of claim 11, wherein the at least one arm of the first lock hinge socket extends outwardly from around a third corner of the lid, and the at least one arm of the second lock hinge socket extends outwardly from around a fourth corner of the lid, the third and fourth corners being on the same side of the lid.

13. The junction box assembly of claim 10, wherein at least one of the first and second lock hinge sockets further includes a first recessed wall that inwardly extends from a sidewall of the lid perimeter wall.

14. The junction box assembly of claim 13, further including a locking pin at least partially positioned within the upper head portion of at least one of the third and fourth hinge arms, the first recessed wall having an aperture that is adjacent to a lock body of the locking pin when the upper head portion of the associated third or fourth hinge arm is positioned within the second recess of the associated first or second lock hinge socket, the lock body being sized and positioned for axial displacement into and from the aperture in the first recessed wall when the lock body is at a first angular orientation, and sized to prevent axial displacement of the lock body into and from the aperture when the lock body is at a second angular orientation, the second angular orientation being different than the first angular orientation, and
wherein the associated third or fourth hinge arm is not removable from the second recess when the lock body is positioned within the aperture of the first recessed wall.

15. The junction box assembly of claim 10, wherein the at least one arm of each of the first and second lock hinge sockets outwardly extends away from the lid perimeter wall to a distal end of the at least one arm of the first or second lock hinge sockets, the second recess being inwardly offset from the distal end of the at least one arm of the corresponding first or second lock hinge socket.

16. The junction box assembly of claim 10, further comprising a gasket formed into an upper edge of the box perimeter wall, at least a portion of the gasket forming a seal between the lid and the box when the lid is secured at the closed position.

17. The junction box assembly of claim 10, wherein at least one of the first and second pairs of hinge brackets comprise a first bracket segment and a second bracket segment, and wherein the junction box assembly further comprises a box hinge keeper, the box hinge keeper including a first leg and a second leg of at least one of the first and second pairs of hinge brackets, the first leg being attached to the first bracket segment and the second leg attached to the second bracket segment, the first and second legs each being attached to opposing ends of an abutment body of the box hinge keeper.

18. The junction box assembly of claim 10, further including, for each of the first and second articulating hinge sockets, at least one lid hinge keeper, the at least one lid hinge keeper and the first recess extending around opposing sides of the upper head portion of the adjacent first or second hinge arm, the at least one lid hinge keeper including at least one retention tab, an upper surface of the at least one retention tab positioned and configured to provide an abutting force against an adjacent lower surface of the lid that at least assists in securing the at least one lid hinge keeper to the lid.

19. The junction box assembly of claim 10, wherein at least one of the first pair of hinge brackets and the second pair of hinge brackets include a pin slot sized to receive insertion of a pin that is coupled to the lower head portion of the corresponding first or second pair of hinge arms, the pin slot configured to accommodate slideable displacement of the pin within the pin slot.

20. The junction box assembly of claim 10, further including a lock bracket assembly comprising a plurality of lock brackets, at least two lock brackets of the plurality of lock brackets attached to one of the box and the lid, and at least one lock bracket of the plurality of lock brackets attached to the other of the box and the lid, the at least one lock bracket being positioned between the at least two lock brackets when the lid is at the closed positon,
wherein each lock bracket of the plurality of lock brackets comprises a hook portion that defines an aperture of the lock bracket, a distal end of the hook portion being separated from an adjacent portion of the associated lock bracket to define an opening to the aperture of the lock bracket, the opening of the at least one lock bracket being vertically offset from the opening of the at least two lock brackets when the lid is in the closed position, and
wherein, when the lid is at the closed position, each of the apertures of the plurality of lock brackets are aligned along a horizontal central axis.
